(19) United States
(12) Patent Application Publication
(10) Pub. No.: US 2009/0314523 A1
(43) Pub. Date: Dec. 24, 2009

(54) Adhesive sheet with base for flexible printed wiring boards, production method therefor, multilayer flexible printed wiring board and flex-rigid printed wiring board

(75) Inventors: Katsuhiko Ito, Koriyama-shi (JP); Tatsuo Yonemoto, Koriyama-shi (JP); Tomoaki Sawada, Koriyama-shi (JP); Ikuo Takahashi, Chiba-shi (JP); Hideshi Tomita, Chiba-shi (JP)

Correspondence Address: EDWARDS ANGELL PALMER & DODGE LLP, P.O. BOX 55874, BOSTON, MA, 02205, US

(73) Assignees: Matsushita Electric Works, Ltd., Kadoma (JP); Nisshinbo Industries, Inc., Tokyo (JP)

(21) Appl. No.: 11/919,139

(22) PCT Filed: Apr. 19, 2006
(86) PCT No.: PCT/JP2006/308227

§ 371 Date: Oct. 24, 2007

(30) Foreign Application Priority Data
Apr. 25, 2005 (JP) 2005-126104

(51) Int. Cl. H05K 1/00; B32B 27/04; B05D 3/00

(52) U.S. Cl. 174/254; 442/149; 427/386

(57) ABSTRACT

An adhesive sheet with a base for flexible printed wiring boards is provided, which has advantages of easiness of machining, excellent moldability, high rigidity and preventing the fall of resin dust particles during machining of a multilayer flexible printed wiring board or a flex-rigid printed wiring board. This adhesive sheet is used for bonding of a flexible printed wiring board made of a polyimide resin, and comprises a woven or nonwoven fabric as the base and a resin composition. The resin composition contains, as essential components, (a) an epoxy resin having two or more of epoxy groups in one molecule; (b) a polycarbodiimide resin dispersible in a solvent, in which the epoxy resin (a) is also dispersible, and having a number average molecular weight of 2000 or more and less than 10000; and (c) an imidazole curing agent. A weight ratio of the component (a) and the component (b) is in a range of 80:20 to 20:80.

### TECHNICAL FIELD

The present invention relates to an adhesive sheet used for bonding of a flexible printed wiring board, and a production method therefor. In addition, the present invention relates to a multilayer flexible printed wiring board and a flex-rigid printed wiring board, which are obtained by use of the adhesive sheet.

### BACKGROUND ART

A conventional multilayer flexible printed wiring board is produced by, for example, the following method. That is, copper foils on both surfaces of a double-sided copper clad flexible substrate made of a polyimide resin are pattern-etched to form inner layer circuits, and then a coverlay made of the polyimide resin is pressure-bonded to the entire surface of each of the inner layer circuits to obtain a flexible printed wiring board. Next, a single-sided copper clad outer-layer flexible substrate is pressure-bonded to each of both surfaces of this flexible printed wiring board through an adhesive agent to obtain the multilayer flexible printed wiring board having a multilayer portion for mounting electronic parts.

On the other hand, a flex-rigid printed wiring board is produced by, for example, the following method. That is, a plurality of prepregs, each of which is obtained by impregnating a resin into a base, are laminated to form a rigid substrate. Next, this rigid substrate is bonded to a flexible printed wiring board prepared in the same manner described above through an adhesive agent to obtain the flex-rigid printed wiring board.

As the adhesive agent used for bonding of the flexible printed wiring board made of the polyimide resin, for example, there are a modified epoxy resin film disclosed in Japanese Patent Publication No. 3506413, and an adhesive agent obtained by impregnating an epoxy resin into a base and then drying the product.

However, each of such a film-like adhesive agent (bonding sheet) and the adhesive agent of the epoxy-resin impregnated base has a problem. The shortcoming in the former case is low rigidity. In the later case, there are problems that the fall of dust particles of the epoxy resin in a semi-cured state easily occurs during punching or routering, and the dust particles scattered on the coverlay of a hinge portion at the build-up stage becomes a cause of the formation of dents.

For these reasons, it is proposed to use an adhesive agent made of a thermoplastic polyimide resin or the like, which is capable of preventing the fall of dust particles, which is. However, when the adhesive agent is used for multilayer flexible printed wiring boards, there are problems that a decrease in rigidity makes accurate machining difficult, and the production process is restricted due to the necessity of high molding temperature.

### SUMMARY OF THE INVENTION

In consideration of the above problems, a primary concern of the present invention is to provide an adhesive sheet with a base for flexible printed wiring boards, which has advantages of easiness of machining, excellent moldability, high rigidity, and preventing the fall of resin dust particles during machining of a multilayer flexible printed wiring board or a flex-rigid printed wiring board. In addition, by using the adhesive sheet, it is possible to provide the multilayer flexible printed wiring board and the flex-rigid printed wiring board, which have a high rigidity and an advantage that the fall of dust particles hardly occurs when bending is performed.

That is, the adhesive sheet with the base for flexible printed wiring boards of the present invention is an adhesive sheet used for bonding of a flexible printed wiring board made of a polyimide resin. The adhesive sheet comprises a woven fabric or a nonwoven fabric as the base and a resin composition. The resin composition contains, as essential components, (a) an epoxy resin having two or more of epoxy groups in a molecule; (b) a polycarbodiimide resin dispersible in a solvent, in which the epoxy resin of the component (a) is also dispersible, and having a number average molecular weight of 2000 or more and less than 10000; and (c) an imidazole curing agent. A weight ratio of the component (a) and the component (b) is in a range of 80:20 to 20:80.

According to the adhesive sheet with the base for flexible printed wiring boards of the present invention, the fall of dust particles can be prevented, a high rigidity can be obtained, and also the occurrence of voids can be prevented to improve the moldability.

As the woven fabric, it is preferred to use a glass cloth. In addition, as the nonwoven fabric, it is preferred to use a glass nonwoven fabric or an organic fiber nonwoven fabric. In these cases, the rigidity can be further increased.

The present invention also provides a multilayer flexible printed wiring board comprising the flexible printed wiring board made of the polyimide resin, and an outer-layer flexible substrate bonded to flexible printed wiring board by use of the adhesive sheet described above. In this case, there are advantages that the fall of dust particles hardly occurs when bending is performed, and a high rigidity is obtained. In addition, since this multilayer flexible printed wiring board has a high glass transition point and a low water absorption coefficient, an improvement in reliability can be achieved.

In addition, the present invention provides a flex-rigid printed wiring board comprising the flexible printed wiring board made of the polyimide resin, and an outer-layer laminate bonded to the flexible printed wiring board by use of the adhesive sheet described above. In this case, there are advantages that the fall of dust particles hardly occurs when bending is performed at a flexible portion, and a high rigidity is obtained. In addition, since this flex-rigid printed wiring board has a high glass transition point and a low water absorption coefficient, an improvement in reliability can be achieved.

Another purpose of the present invention is to provide a method of producing an adhesive sheet with a base for flexible printed wiring boards, which is characterized by the following steps.

That is, this production method comprises the steps of preparing a varnish by dispersing a resin composition into a solvent, the resin composition containing, as essential components,

(a) an epoxy resin having two or more of epoxy groups in a molecule;
(b) a polycarbodiimide resin dispersible in the solvent, in which the epoxy resin of the component (a) is also dispersible, and having a number average molecular weight of 2000 or more and less than 10000; and
(c) an imidazole curing agent;
impregnating the varnish into a base of a woven fabric or a nonwoven fabric; and drying a resultant product.

According to this method, it is possible to obtain the adhesive sheet, which has improved rigidity and moldability, and the capability of preventing the fall of dust particles.

Further characteristics of the present invention and advantages brought thereby will be clearly understood from the best mode for carrying out the invention described below.

### BRIEF EXPLANATION OF THE DRAWINGS

FIG. 1 is a cross-sectional view of a multilayer flexible printed wiring board according to the present invention; and

FIG. 2 is a cross-sectional view of a flex-rigid printed wiring board according to the present invention.

### BEST MODE FOR CARRYING OUT THE INVENTION

The present invention is explained below in detail according to preferred embodiments.

An adhesive sheet with a base for flexible printed wiring boards of the present invention, which is referred hereinafter simply as “adhesive sheet”, is used for bonding of a flexible printed wiring board made of a polyimide resin. The flexible printed wiring board made of the polyimide resin means a wiring board having a circuit pattern formed on a polyimide film with flexibility and insulation performance.

The adhesive sheet is formed with a woven fabric or a nonwoven fabric as the base, and a resin composition. The resin composition contains, as essential components, the following components (a) to (c) explained in detail.

In the present invention, an epoxy resin having two or more of epoxy groups in a molecule is used as the component (a). As such an epoxy resin, a conventional epoxy resin is available. The epoxy resin is not limited on the condition that it can be used for laminates. Concretely speaking, the epoxy resin comprises a bisphenol A type epoxy resin, a bisphenol F type epoxy resin, a bisphenol S type epoxy resin, a naphthalene type epoxy resin, a biphenyl type epoxy resin, a phenol novolac type epoxy resin, a cresol novolac type epoxy resin, an isocyanurate type epoxy resin, a hydantoin type epoxy resin, an alicyclic epoxy resin, a biphenyl type epoxy resin, a polyfunctional type epoxy resin, a brominated epoxy resin, and a phosphorus-modified epoxy resin. These epoxy resins may be used alone or in combination of two or more thereof.

In addition, the number of epoxy groups of the epoxy resin is not specifically limited on the condition that the epoxy resin has two or more of epoxy groups in a molecule. In consideration of manufacturing, it is preferred to use the epoxy resin having five or less of epoxy groups. Due to molecular weight distribution of the epoxy resin, the number of epoxy groups means an average number of epoxy groups per one molecule.

In the present invention, a granular polycarbodiimide resin is used. Such a polycarbodiimide resin can be prepared by a method disclosed in Japanese Patent Early Publication [kokai] No. 51-61599, a method by L. M. Alberin et al. [J. Appl. Polym. Sci., 21, 1999 (1997)], or a method disclosed in Japanese Patent Early Publication [kokai] No. 2-292316. In other words, polycarbodiimide resins produced from organic polyisocyanates in the presence of a catalyst for accelerating carbodiimidization of isocyanate can be used alone or in combination of two or more thereof.

In the above method, the organic polyisocyanates used as the raw material for synthesizing the polycarbodiimide resin comprise, for example, an aromatic polyisocyanate, an aliphatic polyisocyante, an alicyclic polyisocyanate, or a mixture thereof. Concretely speaking, it is possible to use 2,4-tolylene diisocyanate, 2,6-tolylene diisocyanate, a mixture of 2,4-tolylene diisocyanate and 2,6-tolylene diisocyanate, crude tolylene diisocyanate, crude methylene diphenyl diisocyanate, 4,4′,4″-triphenylmethylene triisocyanate, xylene diisocyanate, m-phenylene diisocyanate, naphthylene-1,5-diisocyanate, 4,4′-biphenylene diisocyanate, 4,4′-diphenylmethane diisocyanate (MDI), 3,3′-dimethoxy-biphenyl diisocyanate, 3,3′-dimethyldiphenylmethane-4,4′-diisocyanate, tetramethylxylylene diisocyanate, hexamethylene diisocyanate, isophorone diisocyanate, 4,4′-dicyclohexylmethane diisocyanate, and a mixture thereof.

From the viewpoint of heat resistance and reactivity, it is particularly preferred that the organic polyisocyanate used as the raw material for synthesizing the polycarbodiimide resin in the present invention is an aromatic polyisocyanate. This aromatic polyisocyanate means an isocyanate having two or more of isocyanate groups directly bonded to benzene ring in one molecule. From the reason that general versatility is high, 4,4′-diphenylmethane diisocyanate (MDI) or tolylene diisocyanate (TDI) is preferably used as the aromatic polyisocyanate.

The synthesis of the polycarbodiimide resin from the organic polyisocyanate is performed in the presence of the catalyst for accelerating carbodiimidization of isocyanate. For example, the carbodiimidization catalyst comprises a phosphorus compound such as 1-phenyl-2-phospholene-1-oxide, 3-methyl-1-phenyl-2-phospholene-1-oxide, 1-ethyl-2-phospholene-1-oxide, and 1-methyl-2-phospholene-1-oxide. In these compounds, it is particularly preferred to use 3-methyl-1-phenyl-2-phospholene-1-oxide.

The synthesis of the polycarbodiimide resin from the organic polyisocyanate can be performed without using a solvent. Alternatively, the synthesis may be performed in an appropriate solvent. As the solvent, it is possible to use an alicyclic ether such as tetrahydrofuran, 1,3-dixoane and dioxolan, an aromatic hydrocarbon such as benzene, toluene, xylene and ethylbenzene, a halogenated hydrocarbon such as chlorobenzene, dichlorobenzene, trichlorobenzene, perclene, trichloroethane and dichloroethane, or cyclohexanone, methyl ethyl ketone. It is preferred to use a common solvent, in which both of the polycarbodiimide resin and the epoxy resin of the component (a) are dispersible. In this case, there is an advantage that a varnish can be prepared without separating the polycarbodiimide resin from the solvent. As such a solvent, toluene, methyl ethyl ketone, or cyclohexanone is preferably used.

A reaction temperature in the synthesis reaction of the polycarbodiimide resin is not specifically limited. For example, it is preferred that the reaction temperature is in a range of 40° C. to a boiling point of the solvent used. In addition, it is preferred that a concentration of the organic polyisocyanate used as the raw material is in a range of 5 to 50 wt %, and preferably 10 to 35 wt % with respect to the total amount including the solvent at the start of the carbodiimidization reaction. When the concentration of the organic polyisocyanate is less than 5 wt %, there is an economical problem because it takes a long time period to synthesize the polycarbodiimide resin. On the contrary, when the concentration of the organic polyisocyanate exceeds 50 weight %, there is a fear that gelation occurs in the reaction system during the synthesis.

In addition, the polycarbodiimide resin needs to have a number average molecular weight in a range of 2000 or more and less than 10000. When the number average molecular weight is less than 2000, the fall of dust particles easily occurs. On the other hand, when the number average molecular weight is 10000 or more, the varnish viscosity increases, so that the varnish becomes hard to impregnate into the base, or the moldability lowers due to the occurrence of voids.

In addition, when the occurrence of voids resulting from the carbodiimidization reaction of the remaining isocyanates is observed, the polycarbodiimide resin used in the present invention may be controlled to have an appropriate polymerization degree by use of a terminal sealing agent, which is a compound such as monoisocyanate reactive with the terminal isocyanate of the carbodiimide compound. As the monoisocyanate used as the terminal sealing agent, for example, it is possible to use phenylisocyanate, (ortho, meta, para)-tolylisocyanate, dimethylphenyl isocyanate, cyclohexyl isocyanate and methyl isocyanate.

Besides the above compounds, the compound reactive with the terminal isocyanate as the terminal sealing agent comprises an aliphatic compound, aromatic compound, and an alicyclic compound. For example, it is possible to use a compound having —OH group such as methanol, ethanol, phenol, cyclohexanol, N-methylethanol amine, polyethylene glycol monomethyl ether, polypropylene glycol monomethyl ether, a compound having —NH₂ group such as butylamine, and cyclohexylamine, a compound having —COOH group such as propionic acid, benzoic acid, cyclohexane carboxylic acid, a compound having —SH group such as ethyl mercaptan, allyl mercaptan and thiophenol, and a compound having —NH alkyl terminal.

As described in Japanese Patent Publication No. 3506413, a mixture of the polycarbodiimide resin and the epoxy resin can have a film-like form. In this case, it is possible to improve the flexibility of the adhesive sheet, and reduce the fall of resin dust particles from an edge of the adhesive sheet during punching or routering.

In this regard, the common solvent, in which the components (a) and (b) are dispersible, comprises toluene, methyl ethyl ketone, and cyclohexanone. These solvents can be used alone or in combination of two or more thereof. To prepare a varnish, which is impregnated into the base, when the components (a) and (b) are mixed by use of the common solvent, in which the polycarbodiimide resin and the epoxy resin are dispersible, the obtained vanish shows high compatibility without separation between the epoxy resin and the polycarbodiimide resin. In addition, granular crystals where the component (b) is captured in the component (a) are obtained. In the case of using the thus prepared varnish, even when the other epoxy resin or a curing agent is used at the same time, there is no side reaction with the polycarbodiimide resin. As a result, the varnish becomes stable for an extended time period. When the side reaction happens, it may be difficult to impregnate the varnish into the base due to an increase in viscosity of the varnish or gelation of the vanish.

Furthermore, when the adhesive sheet is produced by use of the thus prepared varnish, it is possible to obtain the adhesive sheet having uniform quality because the epoxy resin and the polycarbodiimide resin are kept in an uniform state without separation therebetween in an adhesive resin layer formed by the varnish.

In addition, a weight ratio of the component (a) and the component (b) needs to be in a range of 80:20 to 20:80. When the compounding amount of the polycarbodiimide resin of the component (b) is less than 20 wt % with respect to the total amount of the polycarbodiimide resin and the epoxy resin of the component (a), the effect of preventing the fall of dust particles at the time of machining is lost. On the other hand, when the compounding amount exceeds 80 wt %, it becomes difficult to ensure the moldability.

In the present invention, an imidazole curing agent is used as the component (c) to cure the resin composition. The imidazole curing agent is not specifically limited on the condition that it functions as a curing agent of the epoxy resin. For example, it is possible to use 2-ethyl-4-methylimidazole (2E4MZ), 2-phenylimidazole (2P4Z), and 2-phenyl-4-methyl-5-hydroxymethylimidazole (2P4 MHZ). A compounding amount of the imidazole curing agent can be appropriately determined.

The resin composition of the present invention contains the above-described components (a) to (c) as the essential components. If necessary, an additive (filler) functioning as a flame retardants assistant or a thickener may be used at the time of preparing the resin composition. This additive is not limited to a specific one. For example, it is possible to use a silica powder, a metal hydrate powder such as aluminum hydroxide and magnesium hydroxide, or an inorganic filler comprising a clay mineral powder such as talc and clay. These additives can be used alone, or in combination of two or more thereof.

The adhesive sheet can be produced, as described below. First, the components (a) to (c) described above are mixed. If necessary, an additive such as a film-forming agent may be added. Thus, a varnish of the resin composition is prepared. Next, this varnish is impregnated into a woven fabric or a nonwoven fabric used as the base. At this time, a resin content can be set within a range of 30 to 80 wt % with respect to the total weight of the adhesive sheet. Subsequently, the varnish impregnated base is heated at a temperature of, for example, 130 to 180° C. for 2 to 20 minutes, so that the solvent is removed, the varnish impregnated base is dried in a semi-cured state (B-stage). Thus, the adhesive sheet can be obtained.

As the woven fabric, it is preferred to use a glass cloth. Since the glass cloth has a higher rigidity than the other woven fabrics, it is possible to further improve the rigidity of the adhesive sheet. On the other hand, as the nonwoven fabric, it is preferred to use a glass nonwoven fabric (glass paper) or an organic fiber nonwoven fabric. Since the glass nonwoven fabric and the organic fiber nonwoven fabric has a higher rigidity than the other nonwoven fabrics, it is possible to further improve the rigidity of the adhesive sheet. The organic fiber for the organic fiber nonwoven fabric is not limited to a specific one. For example, it is possible to use an aramid fiber, a polyester fiber, a polyimide fiber, or a polyacrylic fiber. In addition, it is preferred that a thickness of the woven fabric or the nonwoven fabric is not greater than 0.2 mm.

By using the base described above, the adhesive sheet having a higher rigidity than a conventional film-like bonding sheet can be obtained, so that it becomes easy to produce printed wiring boards. In the thus obtained adhesive sheet, it is possible to prevent the fall of dust particles at the time of punching or routering. In addition, since the occurrence of voids can be prevented at the time of molding, the moldability can be further improved. Furthermore, a high rigidity can be obtained after the molding. In particular, even when the number of layers is increased in a multilayer portion of a multilayer flexible printed wiring board or a flex-rigid printed wiring board, a sufficiently high rigidity can be ensured at a flexible portion by use of the adhesive sheet of the present invention.

Next, it is concretely explained about the case where the thus obtained adhesive sheet is used for bonding of a flexible printed wiring board made of a polyimide resin.

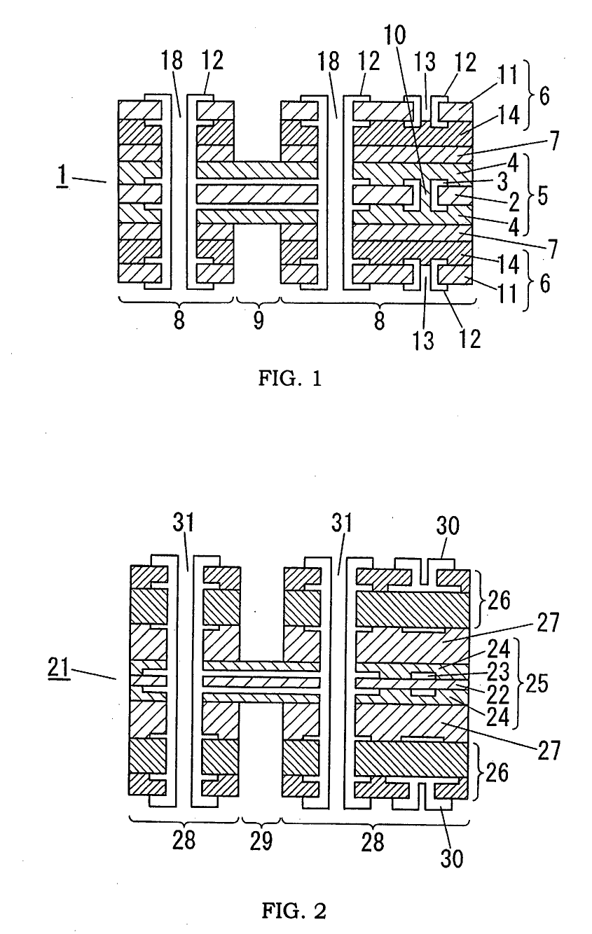

FIG. 1 shows a multilayer flexible printed wiring board 1 produced by use of the adhesive sheet 7 of the present invention. In the present invention, the multilayer flexible printed wiring board 1 means a multilayer structure of flexible substrates made of a resin such as polyimide resin having flexibility. This multilayer flexible printed wiring board 1 can be produced by bonding an outer-layer flexible substrate 6 to a flexible printed wiring board 5 made of the polyimide resin with use of the adhesive sheet 7.

Concretely speaking, inner layer circuits 3 are formed on both surfaces of a flexible substrate material 2 made of the polyimide resin such as a polyimide film. After one of the inner layer circuits 3 is electrically connected to the other inner layer circuit via through holes 10, the flexible substrate material 2 is covered with a coverlay 4 made of the polyimide resin to obtain the flexible printed wiring board 5. The coverlay 4 may be omitted.

Then, the outer-layer flexible substrate 6 is bonded to the thus obtained flexible printed wiring board 5 by use of the adhesive sheet 7 to obtain the multilayer flexible printed wiring board 1. In this regard, the outer-layer flexible substrate 6 can be obtained by forming outer layer circuits 12 on both surfaces of a flexible substrate material 11 made of the polyimide resin such as a polyimide film, electrically connecting one of the outer layer circuits 12 to the other outer layer circuit via a through hole 13, and then coating one surface of the flexible substrate material 11 with a flexible substrate material 14 made of the polyimide resin. After the outer-layer flexible substrate 6 is bonded, the inner layer circuits 3 are electrically connected to the outer layer circuits 12 via through holes 18. In addition, as shown in FIG. 1, the outer-layer flexible substrates 6 may be bonded at plural locations to the flexible printed wiring board 5. In this case, a multilayer portion 8 is positioned at a location where the outer-layer flexible substrate 6 is bonded to the flexible printed wiring board 5, and a flexible portion 9 is positioned at a location where the flexible printed wiring board 5 is exposed to outside without being bonded with the outer-layer flexible substrates 6.

As described above, each of both surfaces of the adhesive sheet 7 contacts the polyimide resin. That is, one surface of the adhesive sheet 7 contacts the polyimide resin of the coverlay 4, and the other surface of the adhesive sheet contacts the polyimide resin of the outer-layer flexible substrate 6. When the coverlay 4 is not used, the one surface of the adhesive sheet 7 contacts the polyimide resin of the flexible substrate material 2. In addition, as shown in FIG. 1, when the flexible portion 9 is formed between adjacent multilayer portions 8, the multilayer flexible printed wiring board 1 can be easily bended at the flexible portion 9. In the multilayer flexible printed wiring board 1 produced by use of the adhesive sheet 7 of the present invention, it is possible to obtain a high rigidity, prevent the occurrence of voids, and achieve the advantage that the fall of dust particles hardly occurs even when bending is performed.

On the other hand, FIG. 2 shows a flex-rigid printed wiring board 21 produced by use of the adhesive sheet 27 of the present invention. In the present invention, the flex-rigid printed wiring board 21 means a multilayer structure of a flexible substrate made of a resin such as the polyimide resin having flexibility and a rigid substrate not having flexibility such as a glass epoxy. This flex-rigid printed wiring board 21 can be produced by bonding an outer-layer laminate 26 to a flexible printed wiring board 25 made of the polyimide resin with use of the adhesive sheet 27.

Concretely speaking, as described in the case of FIG. 1, inner layer circuits 23 are formed on both surfaces of a flexible substrate material 22 made of the polyimide resin such as a polyimide film. Then, the flexible substrate material 22 is covered with a coverlay 24 made of the polyimide resin to obtain the flexible printed wiring board 25. The coverlay 24 may be omitted.

Then, the outer-layer laminate 26 is bonded to the thus obtained flexible printed wiring board 25 by use of the adhesive sheet 27 to obtain the flex-rigid printed wiring board 21. In this regard, the outer-layer laminate 26 can be produced by preparing a laminate of plural sheets, each of which is obtained by impregnating a resin such as an epoxy resin into a base such as a glass cloth, and then drying the resin impregnated base, pressure-bonding metal foils such as copper foils to both surfaces of the laminate under a heating condition, and forming outer layer circuits 30 by etching. If necessary, the number of layers of the outer-layer laminate 26 may be appropriately increased by a build-up method. After the outer-layer laminate 26 is bonded, the inner layer circuits 23 are electrically connected to the outer layer circuits 30 via through holes 31. In addition, as shown in FIG. 2, when producing the flex-rigid printed wiring board 21, the outer-layer laminates 26 are bonded at plural locations to the flexible printed wiring board 25. In this case, a rigid multilayer portion 28 is positioned at a location where the outer-layer laminates 26 are bonded to the flexible printed wiring board 25, and a flexible portion 29 is positioned at a location where the flexible printed wiring board 25 is exposed to outside without being bonded with the outer-layer laminate 26.

As described above, each of both surfaces of the adhesive sheet 27 contacts the polyimide resin. That is, one surface of the adhesive sheet 27 contacts the polyimide resin of the coverlay 24, and the other surface of the adhesive sheet contacts the polyimide resin of the outer-layer laminate 26. When the coverlay 24 is not used, the one surface of the adhesive sheet 27 contacts the polyimide resin of the flexible substrate material 22. In addition, as shown in FIG. 2, when the flexible portion 29 is formed between adjacent multilayer portions 28, the flex-rigid printed wiring board 21 can be easily bended at the flexible portion 29. In the flex-rigid printed wiring board 21 produced by use of the adhesive sheet 27 of the present invention, it is possible to obtain a high rigidity, prevent the occurrence of voids, and achieve the advantage that the fall of dust particles hardly occurs even when bending is performed at the flexible portion 29.

By using the above-described adhesive sheet of the present invention for bonding of the flexible printed wiring board in the multilayer flexible printed wiring board described above or the flex-rigid printed wiring board described above, the fall of dust particles from the adhesive sheet at the time of punching can be reduced. In particular, the rigidity of the multilayer flexible printed wiring board can be effectively improved by the base of the adhesive sheet. Moreover, according to the present invention, since each of the multilayer flexible printed wiring board and the flex-rigid printed wiring board has a high glass transition point and a low water absorption coefficient, an improvement in reliability can be achieved.

### EXAMPLES

The present invention is concretely explained below according to Examples. However, the present invention is not limited to these Examples.

### Preparation of Varnishes with Resin Compositions of Examples 1 to 4

As the epoxy resin, an acetone solution of a brominated epoxy resin “DER530A80” (epoxy equivalent: 430 g/eq, sold content concentration: 80 wt %) manufactured by The Dow Chemical Company, and a methyl ethyl ketone solution of a phosphorus-modified epoxy resin “FX305EK70” (epoxy equivalent: 500 g/eq, sold content concentration: 70 wt %) manufactured by Tohto Kasei Co., Ltd. were used.

To prepare the polycarbodiimide resin, diphenylmethane diisocyanate was used as the raw material, and a mixed solvent where a weight ratio of toluene and methyl ethyl ketone (MEK) is 8:2 was used. The number average molecular weight of the polycarbodiimide resin is about 5000. Next, a phenol novolac type epoxy resin (epoxy equivalent: 180 g/eq) was mixed with this resin solution such that a weight ratio of polycarbodiimide resin:epoxy resin is 2:1. A resultant mixture contains granular crystals. In this case, 2-ethyl-4-methylimidazole (2E4MZ) was used as the curing agent.

The epoxy resin described above and the polycarbodiimide resin were blended at a predetermined composition ratio, as shown in TABLE 1. With respect to Examples 3 and 4, aluminum hydroxide was further added as an inorganic filler. A resultant mixture was mixed for about 90 minutes by using a homomixer (manufactured by Tokushu Kikai Kogyo Co., Ltd.) at about 1000 rpm to prepare a varnish. Subsequently, 2-ethyl-4-methylimidazole (2E4MZ) was added as the curing agent to this varnish, and then agitated for about 15 minutes. Then, deaeration was performed to obtain the varnish of the resin composition. In TABLE 1, each of the compositions is based on parts by weight.

### Preparation of Varnishes with Resin Compositions of Comparative Examples 1 and 2

As the epoxy resin, a brominated bisphenol A type epoxy resin “YDB-500” (manufactured by Tohto Kasei Co., Ltd.; epoxy equivalent: 500 g/eq), and a cresol novolac type epoxy resin “YDCN-220” (manufactured by Tohto Kasei Co., Ltd.; epoxy equivalent: 220 g/eq) were used.

As the curing agent, dicyandiamide (molecular weight: 84, theoretical active hydrogen equivalent: 21), and 2-ethyl-4-methylimidazole (2E4MZ) were used. In addition, methyl ethyl ketone (MEK), methoxypropanol (MP) and dimethylformamide (DMF) were used as the solvent.

In addition, a polycarbodiimide resin was prepared according to Example 1 (e.g., the paragraph [0034]) disclosed in Japanese Patent Publication No. 3506413. That is, the polycarbodiimide resin was synthesized by use of 4,4′-diphenylmethane diisocyanate and phenylisocyanate. The number average molecular weight of the polycarbodiimide resin is 20000.

In the Comparative Example 1, the epoxy resin and the polycarbodiimide resin were blended at a predetermined composition ratio, as shown in TABLE 1. A resultant mixture was mixed for about 90 minutes by using a homomixer (manufactured by Tokushu Kikai Kogyo Co., Ltd.) at about 1000 rpm to prepare a varnish. Subsequently, 2-ethyl-4-methylimidazole (2E4MZ) was added as the curing agent to this varnish, and then agitated for about 15 minutes. Then, deaeration was performed to obtain the varnish of the resin composition.

In the Comparative Example 2, the above-described two kinds of epoxy resins were blended at a predetermined composition ratio, as shown in TABLE 1. A resultant mixture was mixed for about 90 minutes by using a homomixer (manufactured by Tokushu Kikai Kogyo Co., Ltd.) at about 1000 rpm to prepare a varnish. Subsequently, dicyandiamide and 2-ethyl-4-methylimidazole (2E4MZ) were added as the curing agent to this varnish, and then agitated for about 15 minutes. Then, deaeration was performed to obtain the varnish of the resin composition.

### Comparative Examples 3

NIKAFLEX®. “SAFD” (manufactured by NIKKAN INDUSTRIES Co., Ltd.; thickness: 40 μm) was used as the adhesive sheet (a film without the base).

### <Production of Adhesive Sheets>

A glass cloth 2116 type “WEA116E” (manufactured by Nitto Boseki Co., Ltd.; thickness: 0.1 mm) was used as a woven fabric for the base. In addition, an aramid nonwoven fabric “Thermount®” (manufactured by DuPont, basic weight: 30 g=thickness: 0.04 mm) was used as a nonwoven fabric for the base.

The varnish prepared by the above-described method was impregnated into the base such that the resin content is in a range of 40 to 80 weight % with respect to the total weight of the adhesive sheet. Subsequently, a resultant product was heated for 5 minutes at a temperature of about 130° C. to 180° C. by a noncontact type heating unit to dry and remove the solvent in the varnish. As a result, the adhesive sheet in a semi-cured state (B-stage) was obtained. By using the thus obtained adhesive sheets, a dust fall test, evaluation of moldability, and an elastic modulus measurement were performed.

### <Dust Fall Test>

The adhesive sheet that is a square 10 cm on a side was cut by a cutter knife to obtain 10 rectangular adhesive pieces each having a width of 5 mm. At this time, a weight of resin dust particles generated from the cut edges was measured.

### <Moldability>

A copper foil of a laminate “R-1766” (manufactured by Matsushita Electric Works Co., Ltd.; thickness: 0.2 mm, copper foil thickness: 35 μm) was etched to form a circuit pattern, and then an inner layer treatment (black oxide treatment) was performed. The adhesive sheet was placed as an interlayer insulation material between this laminate and a flexible printed wiring board “R-F775” (manufactured by Matsushita Electric Works Ltd., copper foil thickness: 18 μm), and then a resultant laminate was pressure-bonded at a molding temperature of 180° C. for 90 minutes under a pressure of 2.94 MPa to obtain a multilayer wiring board, as shown in FIG. 2. The occurrence of voids at a portion where the inner layer circuit is formed was observed.

### <Elastic Modulus>

A laminate obtained by placing copper foils on both surfaces of the adhesive sheet was pressure-molded at a molding temperature of 180° C. for 90 minutes under a pressure of 2.94 MPa to obtain a double-sided copper clad laminate having a thickness of 1.6 mm. A measurement sample was prepared by overall etching the copper foils of the double-sided copper clad laminate. By using this measurement sample, the elastic modulus was measured in accordance with JIS C6481.

Results of the dust fall test, the evaluation of moldability and the elastic modulus measurement are listed in TABLE 1.

TABLE 1

| | | Example | | | | Comparative Example | | |
|---|---|---|---|---|---|---|---|---|
| | | 1 | 2 | 3 | 4 | 1 | 2 | 3 |
| Epoxy resin | DER530A80 | 50 | | | | 50 | | |
| | FX305EK70 | | 30 | 70 | 70 | | | |
| | YDB-500 | | | | | | 90 | |
| | YDCN-220 | | | | | | 10 | |
| Polycarbodiimide | number average | 50 | 70 | 30 | 30 | | | |
| resin | molecular weight: | | | | | | | |
| | 5000 | | | | | | | |
| | number average | | | | | 50 | | |
| | molecular weight: | | | | | | | |
| | 20000 | | | | | | | |
| Curing agent | Dicyandiamide | | | | | | 2 | |
| | 2E4MZ | 0.5 | 0.1 | 0.5 | 0.5 | 0.5 | 0.1 | |
| Inorganic filler | Aluminum hydroxide | | | 40 | 40 | | | |

| | | | | | | | |
|---|---|---|---|---|---|---|---|
| Base | woven | woven | woven | nonwoven | woven | woven | “SAFD” 1 |
| Dust fall test (mg/m) | 0 | 0 | 0 | 0 | 0 | 200 | 0 |
| Moldability (the occurrence of voids) | none | none | none | none | observed | none | none |
| Elastic modulus (GPa) | 23 | 23 | 24 | 13 | 23 | 23 | 3 |

1 NIKAFLEX ®. “SAFD” is a film without Base.

As understood from TABLE 1, with respect to each of the adhesive sheets of Examples 1 to 4, the results show that the fall of dust particles can be prevented, a high rigidity can be obtained, and also the occurrence of voids can be prevented to improve the moldability.

On the other hand, with respect to the adhesive sheet of Comparative Example 1 where the number average molecular weight of the polycarbodiimide resin exceeds 10000, the results show that the moldability lowers due to the occurrence of voids. In addition, with respect to the adhesive sheet of Comparative Example 2 where no polycarbodiimide resin was used, the results show that the fall of dust particles can not be prevented. Furthermore, with respect to the adhesive sheet of Comparative Example 3 not having the base, the results show that the rigidity significantly decreases.

### INDUSTRIAL APPLICABILITY

Thus, since the adhesive sheet of the present invention is preferably used to produce the multilayer flexible printed wiring board and the flex-rigid printed wiring board, and has advantages of providing excellent rigidity and moldability, and preventing the fall of dust particles, it is expected to be widely utilized in the relevant technical fields.

1. An adhesive sheet with a base, which is used for bonding of a flexible printed wiring board made of a polyimide resin, and comprises a woven fabric or a nonwoven fabric as the base and a resin composition,
wherein said resin composition contains, as essential components,
(a) an epoxy resin having two or more of epoxy groups in a molecule;
(b) a polycarbodiimide resin dispersible in a solvent, in which said epoxy resin of the component (a) is also dispersible, and having a number average molecular weight of 2000 or more and less than 10000;
(c) an imidazole curing agent, and
a weight ratio of the component (a) and the component (b) is in a range of 80:20 to 20:80.

2. The adhesive sheet as set forth in claim 1, wherein said woven fabric is a glass cloth.

3. The adhesive sheet as set forth in claim 1, wherein said nonwoven fabric is a glass nonwoven fabric or an organic fiber nonwoven fabric.

4. A multilayer flexible printed wiring board comprising a flexible printed wiring board made of a polyimide resin, and an outer-layer flexible substrate bonded to the flexible printed wiring board by use of the adhesive sheet as set forth in claims 1.

5. A flex-rigid printed wiring board comprising a flexible printed wiring board made of a polyimide resin, and an outer-layer laminate bonded to the flexible printed wiring board by use of the adhesive sheet as set forth in claims 1.

6. A method of producing an adhesive sheet with a base, which is used for bonding of a flexible printed wiring board made of a polyimde resin, the method comprising the steps of:
preparing a varnish by dispersing a resin composition into a solvent, said resin composition containing, as essential components, (a) an epoxy resin having two or more of epoxy groups in a molecule; (b) a polycarbodiimide resin dispersible in a solvent, in which said epoxy resin of the component (a) is also dispersible, and having a number average molecular weight of 2000 or more and less than 10000; and (c) an imidazole curing agent;
impregnating said varnish into a woven fabric or a nonwoven fabric as the base; and drying a resultant product.

7. A multilayer flexible printed wiring board comprising a flexible printed wiring board made of a polyimide resin, and an outer-layer flexible substrate bonded to the flexible printed wiring board by use of the adhesive sheet as set forth in claim 2.

8. A multilayer flexible printed wiring board comprising a flexible printed wiring board made of a polyimide resin, and an outer-layer flexible substrate bonded to the flexible printed wiring board by use of the adhesive sheet as set forth in claim 3.

9. A flex-rigid printed wiring board comprising a flexible printed wiring board made of a polyimide resin, and an outer-layer laminate bonded to the flexible printed wiring board by use of the adhesive sheet as set forth in claim 2.

10. A flex-rigid printed wiring board comprising a flexible printed wiring board made of a polyimide resin, and an outer-layer laminate bonded to the flexible printed wiring board by use of the adhesive sheet as set forth in claim 3.
